(19) United States
(12) Patent Application Publication
(10) Pub. No.: US 2024/0218511 A1
(43) Pub. Date: Jul. 4, 2024

(54) SUBSTRATE DEGASSING METHOD AND SEMICONDUCTOR FABRICATION METHOD USING THE SAME

(71) Applicant: Samsung Electronics Co., Ltd., Suwon-si (KR)

(72) Inventors: DONG-GU KIM, Suwon-si (KR); GIDUCK KWEON, Suwon-si (KR); IN-YOUNG KIM, Suwon-si (KR); DONGHYUN JANG, Suwon-si (KR); SUNG-WOO JEON, Suwon-si (KR)

(21) Appl. No.: 18/228,191

(22) Filed: Jul. 31, 2023

(30) Foreign Application Priority Data
Dec. 28, 2022 (KR) 10-2022-0186918

(51) Int. Cl. C23C 16/455; C23C 16/458; H01L 21/768

(52) U.S. Cl. CPC C23C 16/45557; C23C 16/45561; C23C 16/4583; H01L 21/76829

(57) ABSTRACT

Disclosed are substrate degassing methods and semiconductor fabrication methods using the same. The substrate degassing method comprises operating a vacuum pump associated with a process chamber to remove gas from the process chamber, preparing a substrate in the process chamber, blocking introduction of gas into the process chamber, and repeatedly opening and closing a pump valve at least two times. The pump valve inhibits the vacuum pump from removing gas from the process chamber when closed and permits the vacuum pump to remove gas from the process chamber when opened. The step of closing the pump valve is performed for a first time period. The step of opening the pump valve is performed for a second time period. The first time period is greater than the second time period.

### CROSS-REFERENCE TO RELATED APPLICATION

This U.S. nonprovisional application claims priority under 35 U.S.C § 119 to Korean Patent Application No. 10-2022-0186918 filed on Dec. 28, 2022 in the Korean Intellectual Property Office, the disclosure of which is hereby incorporated by reference in its entirety.

### BACKGROUND

The present inventive concepts relate to a substrate degassing method and a semiconductor fabrication method using the same, and more particularly, to a substrate degassing method including application of a vacuum to a process chamber and a substrate fabrication method using the same.

Semiconductor devices have an important role in the electronic industry because of their small size, multi-functionality, and/or low fabrication cost. Semiconductor devices are increasingly integrated with the development of electronic industry. Line widths of patterns of semiconductor devices continue to be reduced for high integration of the semiconductor devices. However, new exposure techniques and/or expensive exposure techniques are required for the increasing fineness of the patterns such that it is increasingly difficult to highly integrate semiconductor devices.

### SUMMARY

Some embodiments of the present inventive concepts provide a substrate degassing method including cyclically pumping a process chamber and a substrate fabrication method using the same.

Embodiments of the present inventive concepts are not limited to those described herein, and other embodiments which have not been particularly described will be understood to those skilled in the art from the following description.

According to some embodiments of the present inventive concepts, a substrate degassing method may comprise: operating a vacuum pump associated with a process chamber to remove gas from the process chamber; preparing a substrate into the process chamber; blocking introduction of gas into the process chamber; and repeatedly opening and closing a pump valve, wherein the pump valve is opened at least two time and closed at least two times. The pump valve inhibits the vacuum pump from removing gas from the process chamber when closed and permits the vacuum pump to remove gas from the process chamber when opened. The pump valve remains closed for a first time period, remains opened for a second time period, and the first time period may be greater than the second time period.

According to some embodiments of the present inventive concepts, a semiconductor fabrication method may comprise: performing a first semiconductor fabrication process to deposit a first layer on a substrate; degassing the substrate; and performing a second semiconductor fabrication process on the substrate to deposit a second layer on the substrate that is different from the first layer. The step of degassing the substrate may include: operating a vacuum pump associated with a process chamber to remove gas from the process chamber; blocking introduction of gas into the process chamber; closing a pump valve for a first time period; and opening the pump valve for a second time period less than the first time period. The pump valve inhibits the vacuum pump from removing gas from the process chamber when closed and permits the vacuum pump to remove gas from the process chamber when opened. The step of closing the pump valve and the step of opening the pump valve are each performed at least two times.

According to some embodiments of the present inventive concepts, a method of fabricating a semiconductor memory device may comprise: forming a device isolation layer on a semiconductor substrate to define active patterns; forming word lines that extend in a first direction crossing the active patterns and that are buried in the semiconductor substrate; forming bit lines on the active patterns and the word lines, the bit lines extending in a second direction that intersects the first direction; removing a residual gas from the bit lines; and forming a bit-line capping pattern on the bit line. The step of removing the residual gas in the bit lines may include: blocking introduction of gas into a process chamber; and cyclically changing a vacuum pressure of the process chamber.

### BRIEF DESCRIPTION OF THE DRAWINGS

FIG. 1 illustrates a cross-sectional view showing a substrate processing apparatus configured to perform a substrate degassing method according to some embodiments of the present inventive concepts.

FIG. 2 illustrates a flow chart showing a substrate degassing method and a substrate fabrication method using the same according to some embodiments of the present inventive concepts.

FIGS. 3 and 4 illustrate cross-sectional views showing a substrate processing apparatus configured to perform a substrate degassing method according to some embodiments of the present inventive concepts.

FIG. 5 illustrates a graph showing a change in pressure of a process chamber over time in a substrate degassing method according to some embodiments of the present inventive concepts.

FIG. 6 illustrates an enlarged graph partially showing a change in pressure of a process chamber over time in a substrate degassing method according to some embodiments of the present inventive concepts.

FIG. 7 illustrates an enlarged graph partially showing a change in pressure of a process chamber over time in a substrate degassing method according to some embodiments of the present inventive concepts.

FIG. 8 illustrates a plan view of a semiconductor substrate that may be processed using the substrate degassing method and substrate fabrication method according to some embodiments of the present inventive concepts.

FIGS. 9A, 10A, and 11A illustrate cross-sectional views of a semiconductor substrate taken along line I-I′ of FIG. 8.

FIGS. 9B, 10B, and 11B illustrate cross-sectional views of a semiconductor substrate taken along line II-II′ of FIG. 8.

### DETAIL DESCRIPTION OF EMBODIMENTS

The following will now describe some embodiments of the present inventive concepts with reference to the accompanying drawings. Like reference numerals may indicate like components throughout the description.

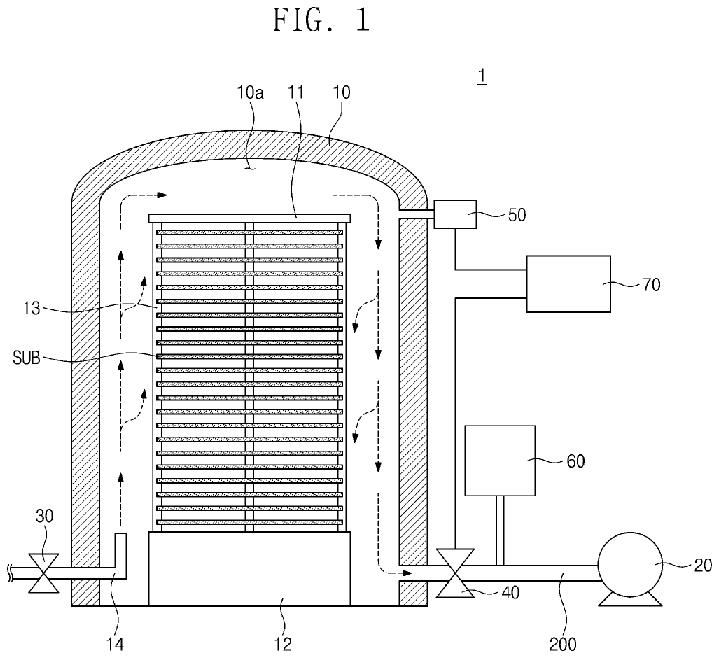

FIG. 1 illustrates a cross-sectional view showing a substrate processing apparatus configured to perform a substrate degassing method according to some embodiments of the present inventive concepts.

Referring to FIG. 1, a substrate processing apparatus 1 may be provided which is configured to perform a substrate degassing method according to some embodiments of the present inventive concepts. The substrate processing apparatus 1 may be a device to perform a semiconductor fabrication process, such as a deposition process. The substrate processing apparatus 1 may supply gases to react and deposit a thin layer on a substrate SUB. For example, the substrate processing apparatus 1 may be a low pressure chemical vapor deposition (LPCVD) apparatus driven under a pressure condition ranging from about 1 Pa to about 300 Pa. The substrate SUB may be a substrate, such as a semiconductor substrate, for fabrication of a semiconductor device, but the present inventive concepts are not limited thereto.

The substrate processing apparatus 1 may include a process chamber 10, a vacuum pump 20, a gas valve 30, a pump valve 40, a pressure gauge 50, an analyzer 60, and a controller 70.

The process chamber 10 may include an upper plate 11, a lower plate 12, a support 13 that provides a plurality of grooves, and a gas supply unit 14. The process chamber 10 may provide an internal space 10a where a deposition process is performed. For example, the internal space 10a of the process chamber 10 may accommodate the upper plate 11, the lower plate 12, the support 13 that provides a plurality of grooves, and the gas supply unit 14. In the following description, when referring to the process chamber 10, unless otherwise indicated, it will be understood that the reference includes the internal space 10a of the process chamber where appropriate. The process chamber 10 may have a hermetic structure to maintain a low pressure state near a vacuum state. The process chamber 10 may be formed of and/or include a material with superior heat resistance. The process chamber 10 (e.g. the chamber housing) may be formed of and/or include a material with excellent corrosion resistance to gases supplied into the process chamber 10. For example, the process chamber 10 may be formed of and/or include yttrium oxide (Y₂O₃), but the present inventive concepts are not limited thereto.

The process chamber 10 may further include a heating unit (not shown). The heating unit may encompass the process chamber 10 and be configured to heat the process chamber 10. For example, the heating unit may increase a temperature of the internal space 10a in the process chamber 10. Thus, a high-temperature semiconductor fabrication process may be performed in the process chamber 10. The heating unit may include a hot wire heating element and/or a heat transfer fluid. For example, the heating unit may use a voltage to heat the hot wire heating element or a high-temperature heat transfer fluid to heat the process chamber 10.

The upper plate 11, the lower plate 12, and the support 13 that provides a plurality of grooves may be positioned on a central portion of the process chamber 10. The upper plate 11 may be positioned over the lower plate 12. The support 13 may be positioned between the lower plate 12 and the upper plate 11. For example, the support 13 may connect the lower plate 12 and the upper plate 11 to each other. The support 13 may be provided in plural. The plurality of grooves provided by the support 13 may be spaced apart from each other in a vertical direction. A portion of a substrate SUB may be disposed in a groove of the plurality of grooves. For example, a plurality of substrates SUB may be disposed spaced apart from each other in a vertical direction such that each substrate SUB of the plurality of substrates SUB has a portion disposed in a groove of the plurality of groove. Therefore, the substrates SUB may be disposed in the process chamber 10 and supported by a groove while being located at different levels.

At least a portion of the gas supply unit 14 may be disposed in the process chamber 10 and positioned on a lateral side of the process chamber 10. In some embodiments, at least a portion of the gas supply unit 14 may be located externally to the process chamber 10. A gas may move through the gas supply unit 14 into the internal space 10a of the process chamber 10. A gas may be supplied through the gas supply unit 14 into the process chamber 10, and the process chamber 10 may be filled with the gas. For example, a gas used for a process in the process chamber 10 may include a source gas, a reaction gas, and a cleaning gas. According to an embodiment of the present inventive concepts, different kinds of gases may be supplied into the process chamber 10 by the gas supply unit 14. In this case, the gas supply unit 14 may be provided in plural, and the plurality of gas supply units 14 may be positioned spaced apart from each other. For example, the plurality of gas supply units 14 may be located on opposing sides of the process chamber or be spaced apart from one another by an interval distance. A gas supply unit 14 may include a pipe having an internal passage through which a gas may be introduced into the process chamber.

The gas valve 30 may be positioned on the gas supply unit 14. The gas valve 30 may include a control unit (not shown). The control unit may control the operation of the gas valve 30 to control an amount of gas that passes through the gas supply unit 14. For example, the gas valve 30 may block a gas from being introduced through the gas supply unit 14 into the process chamber 10 or may control an amount of gas introduced through the gas supply unit 14 into the process chamber 10.

The vacuum pump 20 may be associated with the process chamber 10 and fluidly connected to the internal space 10a of the process chamber 10. As used herein, items described as being “fluidly connected” are configured such that a liquid or gas can flow, or be passed, from one item to the other. For example, the internal space 10a of the process chamber 10 may be fluidly connected through an exhaust line 200 to the vacuum pump 20. Thus, the internal space 10a of the process chamber 10 may maintain a low pressure state through the operation of the vacuum pump 20. The vacuum pump 20 may include, for example, a turbo molecular pump (TMP), a roughing pump, or a combination thereof.

The pump valve 40 may be positioned on and/or fluidly connected to the exhaust line 200 and may control the removal of gas from the process chamber 10. The pump valve 40 may be positioned between the process chamber 10 and the vacuum pump 20 and fluidly connected to the process chamber 10 and the vacuum pump 20. The pump valve 40 may be controlled to be completely or partially opened or closed. For example, when closed the pump valve 40 may disable the fluid connection between the process chamber 10 and the vacuum pump 20 thereby blocking a gas from moving from the process chamber 10 to the vacuum pump 20 or, when opened, may control an amount of gas moving from the process chamber 10 to the vacuum pump 20. The pump valve 40 may be connected to the controller 70 which will be discussed below. The controller 70 may transmit an electrical signal to the pump valve 40, and the pump valve 40 may be driven with the electrical signal to open, close, or partially open the pump valve 40.

The pressure gauge 50 may be associated with the process chamber 10 and fluidly connected to the process chamber. For example, the pressure gauge 50 may be fluidly connected to the internal space 10a of the process chamber 10 and positioned on a lateral side of the process chamber 10. The pressure gauge 50 may measure an internal pressure of the process chamber 10. The pressure gauge 50 may be connected to the controller 70 which will be discussed below. The pressure gauge 50 may provide the controller 70 with information about the pressure of the process chamber 10. A single pressure gauge 50 is illustrated, but the present inventive concepts are not limited thereto. For example, two or more pressure gauges 50 may be provided. In this case, the pressure gauges 50 may measure pressures of upper and lower portions of the process chamber 10, while being disposed spaced apart from each other.

The analyzer 60 may be positioned between the pump valve 40 and the vacuum pump 20. For example, the analyzer 60 may be fluidly connected to the exhaust line 200 between the pump valve 40 and the vacuum pump 20. A gas present in the process chamber 10 may move to the vacuum pump 20 through the pump valve 40 and the exhaust line 200. A portion of gas that passes through the exhaust line 200 may be introduced into the analyzer 60. Thus, the analyzer 60 may analyze I gas present in the process chamber 10 to determine the composition of the gas. For example, the analyzer 60 may be a matrix-assisted laser desorption ionization-time of flight (MALDI-TOF) mass spectrometer. In this sense, the analyzer 60 may be configured such that a laser is used to ionize a gas, and a flight time of ionized ions is measured to determine the composition of the gas.

The controller 70 may be associated with the pressure gauge 50 and the pump valve 40. The controller 70 may receive, from the pressure gauge 50, information about the pressure of the process chamber 10. The controller 70 may provide the pump valve 40 with an electrical signal to drive the pump valve 40 to cause the pump valve to open and close. Based on information about the pressure of the process chamber 10, the controller 70 may operate the pump valve 40 to allow the gas in the process chamber 10 to have a constant pressure. For example, when the gas in the process chamber 10 has a pressure greater than a set pressure, the controller 70 may provide the pump valve 40 with an electrical signal by which the pump valve 40 is opened. When the gas in the process chamber 10 has a pressure less than that a set pressure, the controller 70 may provide the pump valve 40 with an electrical signal by which the pump valve 40 is closed. The controller 70 may be constituted by a plurality of computing devices including programmable logic controllers (PLC) or personal computers (PC).

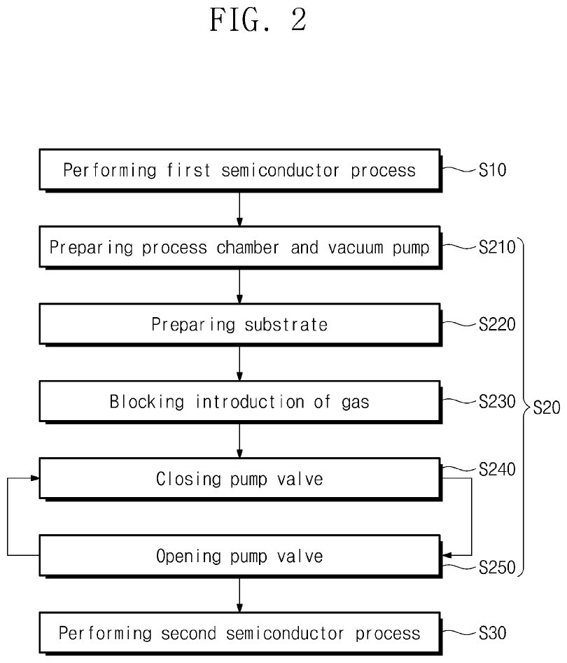

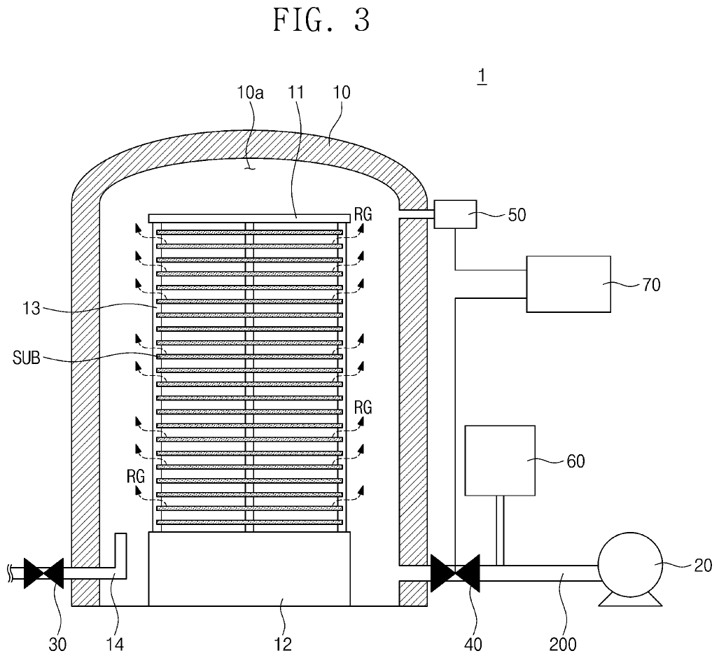

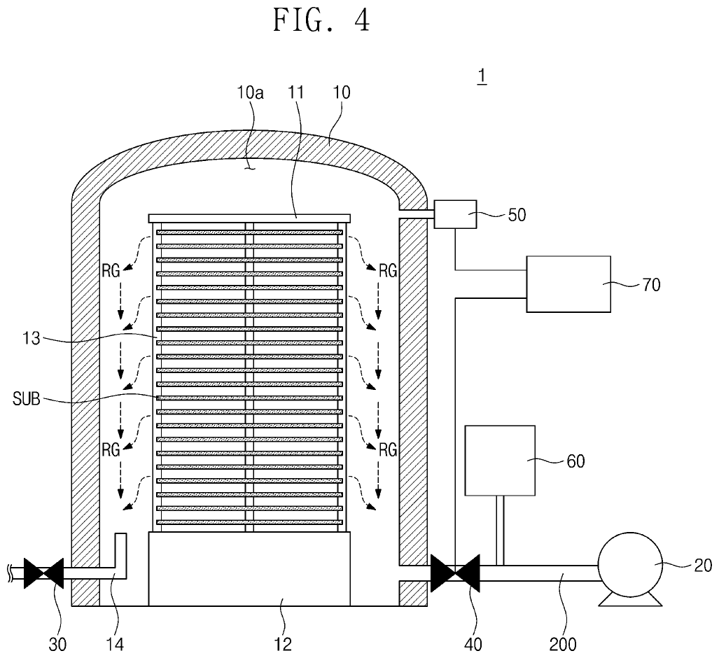

FIG. 2 illustrates a flow chart showing a substrate degassing method and a substrate fabrication method using the same according to some embodiments of the present inventive concepts. FIGS. 3 and 4 illustrate cross-sectional views showing a substrate processing apparatus configured to perform a substrate degassing method according to some embodiments of the present inventive concepts.

In the following, a description of components that are the same as those discussed with reference to FIG. 1 may be omitted while components that are different from those described previously will be discussed in further detail.

Referring to FIGS. 1 and 2, a substrate degassing method and a substrate fabrication method using the same may include performing a first semiconductor fabrication process (S10), degassing a substrate (S20), and performing a second semiconductor fabrication process (S30). The substrate degassing step (S20) may include preparing a process chamber and a vacuum pump (S210), preparing a substrate (S220), blocking introduction of gas (S230), closing a pump valve for a first time period (S240), and opening the pump valve for a second time period (S250). Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

In this description, the substrate degassing step (S20) may include removing a gas present in the substrate SUB. For example, the substrate degassing step (S20) may include removing a residual gas present in a layer deposited by a semiconductor fabrication process on the substrate SUB.

The first semiconductor fabrication process may be performed (S10) as part of manufacturing a semiconductor device. The first semiconductor fabrication process may include a deposition process by which a layer is formed on the substrate SUB. A temperature of the first semiconductor fabrication process may range from about 400° ° C. to about 500° C. A layer formed by the first semiconductor fabrication process on the substrate SUB may include a metallic material. For example, the layer formed by the first semiconductor fabrication process may include tungsten (W). In this case, a gas used for the first semiconductor fabrication process may include tungsten hexafluoride (WF₆), diborane (B₂H₆), silane (SiH₄), dichlorosilane (SiH₂Cl₂), or hydrogen (H₂). One or more of H₂, Cl₂, and HCl may remain in a layer formed by the first semiconductor fabrication process. The first semiconductor fabrication process may be performed in a substrate processing apparatus other than that used for performing the substrate degassing step (S20) and the second semiconductor fabrication process step (S30). For example, after performing the first semiconductor fabrication process the substrate may be moved from a first substrate processing apparatus to a second substrate processing apparatus. An overhead hoist transport (OHT) or the like may be used to transmit the substrates SUB to the substrate processing apparatus 1 of FIG. 1.

The chamber and pump preparation step (S210) may include heating the process chamber 10 and operating the vacuum pump 20. For example, the process chamber 10 may be heated to about 700° C. to about 800° ° C. The process chamber 10 may have a temperature greater than that of a temperature used in the first semiconductor fabrication process. The high temperature of the process chamber 10 may facilitate outward exhaust of residual gas in the substrate SUB. The vacuum pump 20 may continue its operation after the substrate degassing step (S20) during the second semiconductor fabrication process step (S30). For example, the vacuum pump 20 may operate during both the degassing step (S20) and the semiconductor fabrication process step (S30).

The substrate preparation step (S220) may include introducing a substrate SUB into the process chamber 10 such as by loading the process chamber 10 with a plurality of substrates SUB located at different levels. For example, the plurality of substrates SUB may be correspondingly inserted in the plurality of grooves of the support 13. Thus, the plurality of substrates SUB may be spaced apart from each other in a vertical direction.

The substrate preparation step (S220) may further include supplying an inert gas. After loading the plurality of substrates SUB, the inert gas may be supplied into the process chamber 10. The inert gas may be supplied through the gas supply unit 14 into the process chamber 10. Thus, the process chamber 10 may have an increased pressure due to the inert gas. For example, a purge process may be performed to allow the process chamber 10 to replace existing gas with the inert gas.

The gas supply blocking step (S230) may include closing the gas valve 30 on the gas supply unit 14 so that the flow of gas into the process chamber 10 is stopped. The closing of the gas valve 30 may block introduction of the inert gas into the process chamber 10 terminating the purge process. As the pump valve 40 maintains its open state, the inert gas may move from the process chamber 10 through the exhaust line 200 to the vacuum pump 20. For example, the inert gas may be removed from the process chamber 10. Thus, the removal of the inert gas may result in the pressure of the gas in the process chamber 10 to be reduced to a high vacuum state.

Referring to FIGS. 2, 3, and 4, the pump valve close step (S240) and the pump valve open step (S250) may be repeatedly performed. For example, the pump valve close step (S240) and the pump valve open step (S250) may each be performed at least two times. The pump valve close step (S240) may be a step of closing the pump valve 20 to block the fluid connection between the process chamber 10 and the vacuum pump 20. As the process chamber 10 is hermetically sealed, the pump valve close step (S240) results in the process chamber 10 maintaining its vacuum state. As a flow of gas is absent and a vacuum statI is maintainId in the process chamber 10, a residual gas RG may be outwardly discharged from the substrate SUB. For example, a pressure difference may outwardly discharge the residual gas RG present in a layer deposited by the first semiconductor fabrication process on the substrate SUB. As the pump valve close step (S240) includes the outward discharge of the residual gas RG in the substrate SUB, the pressure in the process chamber 10 may increase. The pump valve close step (S240) may keep the pump valve 40 closed for a first time period. The residual gas RG may include one or more of H₂, chlorine (Cl₂), and hydrogen chloride (HCl).

The pump valve open step (S250) may be a step of opening the pump valve 20 to fluidly connect the process chamber 10 and the vacuum pump 20. A gas present in the process chamber 10 may move from the process chamber 10 to the vacuum pump 20 through the pump valve 40. As the vacuum pump 20 removes a gas present in the process chamber 10, the pressure in the process chamber 10 may drop. For example, because the residual gas RG discharged from the substrate SUB is removed from the process chamber 10, the process chamber 10 may return to a high vacuum state. The pump valve close step (S240) may keep the pump valve 40 closed for a second time period.

The pump valve close step (S240) and the pump valve open step (S250) may each result in outwardly discharging the residual gas RG in the substrate SUB and include removing the residual gas RG discharged from the process chamber 10. The pump valve close step (S240) and the pump valve open step (S250) may be repeatedly performed to effectively remove the residual gas RG in the substrate SUB. For example, the pump valve 40 may be closed to disable a flow of gas in a high vacuum state, and the residual gas RG in the substrate SUB may continue to be outwardly discharged from the substrate SUB. The residual gas RG accumulated in the process chamber 10 increases the pressure in the process chamber 10 until the pump valve 40 is opened again at which point the accumulated residual gas RG flows out of the process chamber 10. Compared to keeping the pump valve 40 continually opened, it may be possible to more effectively degas the substrate SUB.

The first time period during which the pump valve 40 is closed may be greater than the second time period during which the pump valve 40 is opened. There may be an extremely small amount of the residual gas RG discharged from the substrate SUB during the first time period. Thus, even though the second time period is less than the first time period, it may be possible to sufficiently remove the residual gas RG present in the process chamber 10. Accordingly, a time required for degassing the substrate SUB may be reduced to increase productivity.

Referring back to FIGS. 1 and 2, the second semiconductor fabrication process may be performed (S30) as part of manufacturing a semiconductor device. The second semiconductor fabrication process may include a deposition process by which a layer is formed on the substrate SUB. The second semiconductor fabrication process step (S30) may include supplying the process chamber 10 with a gas. A gas used for the second semiconductor fabrication process may be supplied through the gas supply unit 14 into the process chamber 10. A temperature of the second semiconductor fabrication process may range from about 700° C. to about 800° C. The temperature of the second semiconductor fabrication process may be greater than that of the first semiconductor fabrication process. For example, the temperature of the second semiconductor fabrication process may be substantially the same as that of the process chamber 10 during the substrate degassing step (S20).

A layer formed by the second semiconductor fabrication process on the substrate SUB may include a dielectric material. For example, the dielectric material may include one or more of silicon nitride, silicon oxide, and silicon oxynitride. The second semiconductor fabrication process may be performed in a substrate processing apparatus that is the same as that in which the substrate degassing step (S20) is performed. The second semiconductor fabrication process may be performed in the substrate processing apparatus 1 of FIG. 1. For example, the substrate degassing step (S20) and the second semiconductor fabrication process step (S30) may be in-situ performed in the same apparatus.

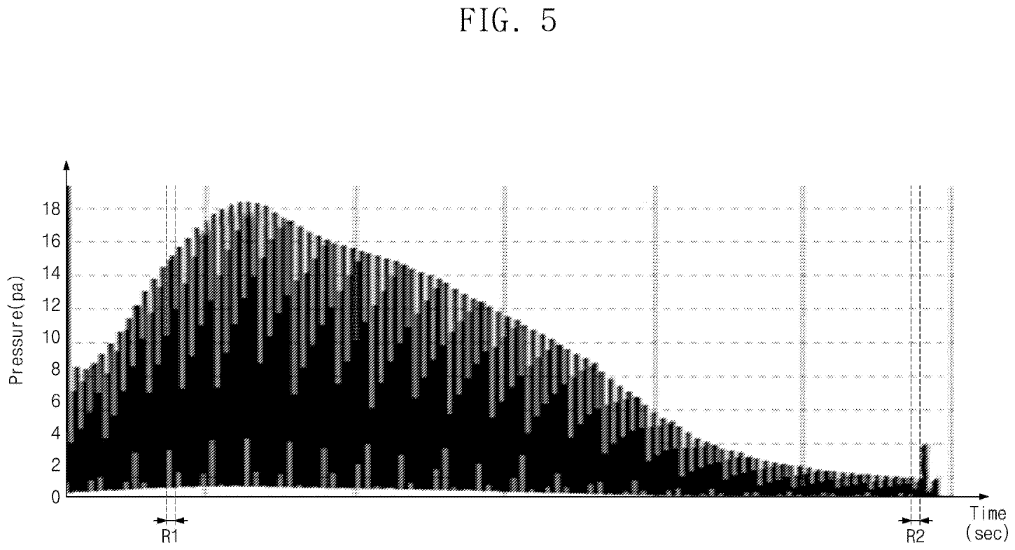

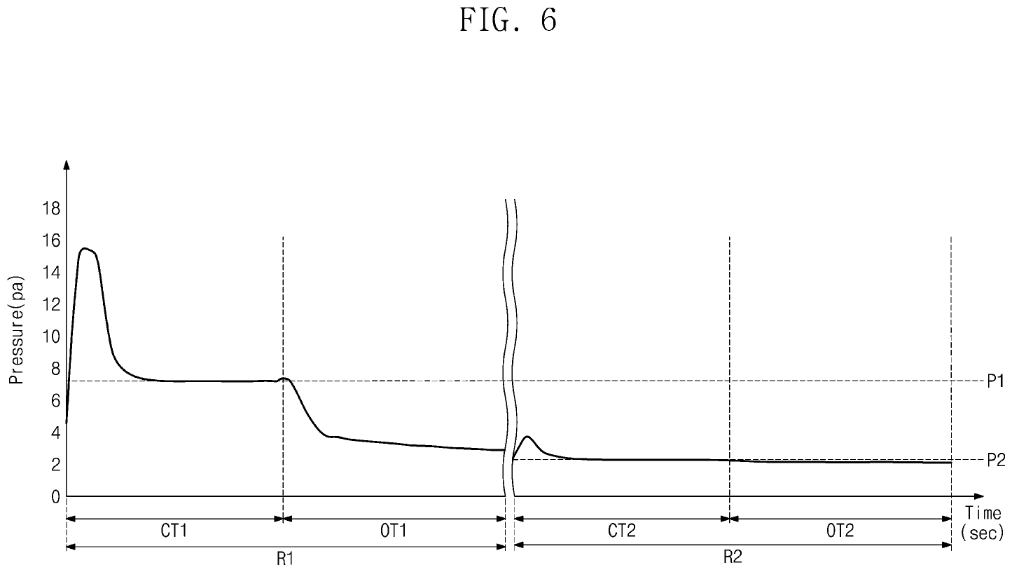

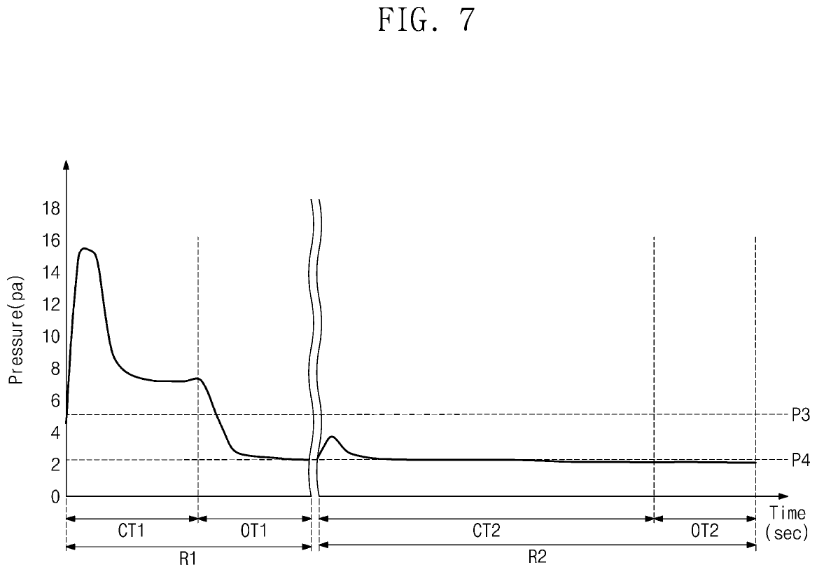

FIG. 5 illustrates a graph showing a change in pressure of a process chamber in a substrate degassing method according to some embodiments of the present inventive concepts. FIG. 6 illustrates an enlarged graph showing a change in pressure of a process chamber in a substrate degassing method according to some embodiments of the present inventive concepts. FIG. 7 illustrates an enlarged graph partially showing a change in pressure of a process chamber in a substrate degassing method according to some embodiments of the present inventive concepts.

In the following, a description of components that are the same as those discussed with reference to FIGS. 2 to 4 may be omitted, while components that are different from those described previously will be discussed in further detail.

Referring to FIGS. 2 to 5, in this description, one cycle may be defined in which each of the pump valve close step (S240) and the pump valve open step (S250) is performed once. The substrate degassing step (S20) may include repeatedly performing the pump valve close step (S240) and the pump valve open step (S250). The substrate degassing step (S20) may include performing at least two times, and several to tens of cycles may be performed. Thus, a pressure of the process chamber 10 may be repeatedly and cyclically changed during the substrate degassing step (S20). A pressure of the process chamber 10 may be measured by the pressure gauge 50 of FIG. 1.

A pressure of the process chamber 10 may be a pressure of the residual gas RG discharged from the substrate SUB. For example, when the pump valve 40 is closed after the gas supply blocking step (S230), the residual gas RG in the substrate SUB may be outwardly discharged and increase a pressure of the process chamber 10. Because the residual gas RG present in the process chamber 10 is removed when the pump valve 40 is opened, the process chamber 10 may have a reduced pressure after the pump valve 40 is opened.

A pressure of the process chamber 10 may increase and then decrease over time. A pressure of the residual gas RG may have one peak. A pressure of the residual gas RG may have a peak in an initial cycle. Embodiments of the present inventive concepts, however, are not limited to those discussed above. For example, a pressure of the residual gas RG may have a plurality of peaks in accordance with a kind of residual gas RG, and may have a peak in a late cycle.

In this description, an initial cycle may indicate a cycle executed within about the first 10% of the substrate degassing step (S20). A late cycle may indicate a cycle executed after about 90% of substrate degassing step (S20) is complete. A first region, designated R1 in FIGS. 5-7, may be one of the initial cycles. A second region, designated as R2 in FIGS. 5-7, may be one of the late cycles.

Referring to FIGS. 3, 4, and 6, the first region R1 may include a first time period CT1 and a second time period OT1, and the second region R2 may include a first time period CT2 and a second time period OT2. Each of the first time periods CT1 and CT2 may be a time during which the pump valve close step (S240) is performed and the pump valve 40 remains closed. Each of the second time periods OT1 and OT2 may be a time during which the pump valve open step (S250) is performed and the pump valve 40 remains open. A pressure of the process chamber 10 during each of the first time periods CT1 and CT2 may be substantially the same as or greater than that of the process chamber 10 during each of the second time periods OT1 and OT2.

For example, a pressure of the process chamber 10 may increase rapidly when the pump valve is first closed and then drop to a nearly constant pressure (or a first pressure P1) during the first time period CT1 of the first region R1. A pressure of the process chamber 10 may decrease during the second time period OT1 of the first region R1 as the pump valve is opened and the residual gas RG is removed. A pressure of the process chamber 10 may rapidly increase and then drop to a nearly constant pressure (or a second pressure P2) during the first time period CT2 of the second region R2. A pressure of the process chamber 10 may not decrease or the decrease may be minimal during the second time period OT2 of the second region R2. A pressure of the process chamber 10 during the second time period OT2 of the second region R2 may remain substantially the same as that of the process chamber 10 during the first time period CT2 of the second region R2 since there may be very little residual gas RG to remove during the later cycles. The second pressure P2 may be less than the first pressure P1. The pressure of the process chamber 10 may decrease from the first time period CT1 of the first region R1 to the first time period CT2 of the second region R2. For example, as the cycle is repeated, an amount of the residual gas RG discharged from the substrate SUB may decrease and thus the pressure of the residual gas RG may be reduced in subsequent cycles.

The first time periods CT1 and CT2 may be the same as each other, the second time periods OT1 and OT2 may be the same as each other, and each of the first time periods CT1 and CT2 may be greater than each of the second time periods OT1 and OT2. For example, the first time period CT1 of the first region R1 may be the same as the first time period CT2 of the second region R2, and the second time period OT1 of the first region R1 may be the same as the second time period OT2 of the second region R2. Each of the first time periods CT1 and CT2 may be, for example, about 1 minute to about 2 minutes. Each of the second time periods OT1 and OT2 may be about 10 seconds to about 30 seconds. According to the embodiment of FIG. 6, an operation of the pump valve 40 may be controlled based on an elapsed time. Therefore, the initial cycle and the late cycle may each have the same time period.

Referring to FIGS. 3, 4, and 7, unlike the embodiment of FIG. 6, an operation of the pump valve 40 may be controlled based on the pressure of the process chamber. The controller 70 may receive, from the pressure gauge 50, information about the pressure of the process chamber 10, and may provide the pump valve 40 with an electrical signal to operate the pump valve 40 based on the pressure.

For example, a pressure of the process chamber 10 may increase during the first time period CT1 of the first region R1. When a pressure of the process chamber 10 is equal to or greater than a third pressure P3 and within first set amount of time, the controller 70 may drive the pump valve 40 to open. For example, the pump valve close step (S240) may be terminated, and then the pump valve open step (S250) may be performed. During the second time period OT1 of the first region R1, a pressure of the process chamber 10 may decrease to be equal to or less than a fourth pressure P4. In some embodiments, the controller 70 may drive the pump valve 40 to close in response to the pressure being less than or equal to the fourth pressure P4. In some embodiments, the second time period may be fixed and the pump valve 40 may close independent of the pressure.

An amount of the residual gas RG discharged from the substrate SUB may decrease as the cycle is performed. For example, a pressure of the process chamber 10 may increase during the first time period CT2 of the second region R2, but may not reach the third pressure P3. When a pressure of the process chamber 10 does not reach the third pressure P3 and the first set amount of time elapsed, the controller 70 may drive the pump valve 40 to open. During the second time period OT2 of the second region R2 the pressure of the process chamber 10 may decrease to be equal to or less than the fourth pressure P. The second semiconductor fabrication process may then be performed. In this case, the pump valve close step (S240) and the pump valve open step (S250) may not be performed any more.

According to the embodiment of FIG. 7, the first set amount of time which corresponds to the first time period CT1 of the first region R1 may be less than the second set amount of time which corresponds to the first time period CT2 of the second region R2. The second time period OT1 of the first region R1 may be substantially the same as the second time period OT2 of the second region R2. For example, as the cycle is performed, an amount of the residual gas RG discharged from the substrate SUB may decrease and thus the first time periods CT1 and CT2 may increase. Unlike the first time periods CT1 and CT2, there may be no change in the second time periods OT1 and OT2 during which the residual gas RG is removed from the process chamber 10. In this case, differently from FIG. 5, a pressure of the process chamber 10 may have no peak. Therefore, a time required for the initial cycle and a time required for the late cycle may be changed, and the time for the late cycle may be longer than the time required for the initial cycle.

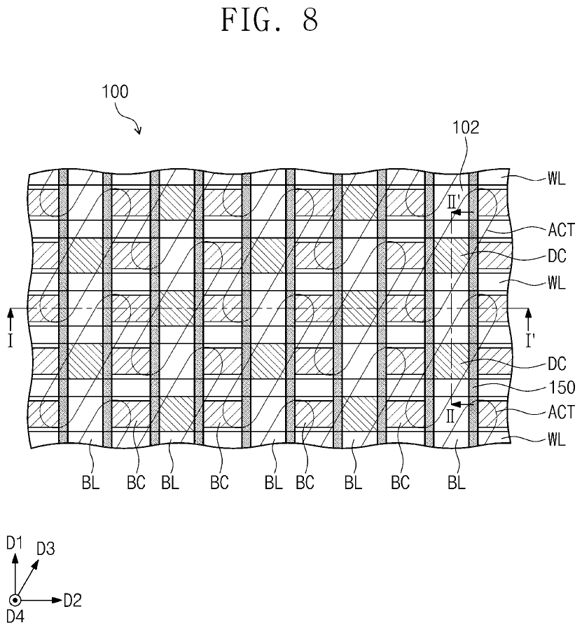

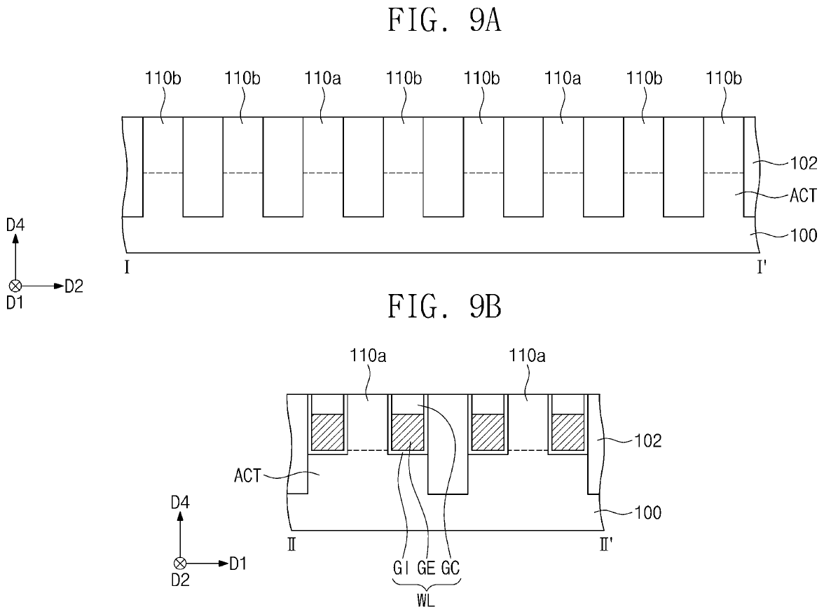

FIG. 8 illustrates a plan view of a semiconductor substrate 100 that may be processed using the substrate degassing method and substrate fabrication method according to some embodiments of the present inventive concepts. These methods may be part of a method of manufacturing a semiconductor device such as a semiconductor chip or semiconductor package. FIGS. 9A, 10A, and 11A illustrate cross-sectional views taken along line I-I′ of FIG. 8. FIGS. 9B, 10B, and 11B illustrate cross-sectional views taken along line II-II′ of FIG. 8.

Referring to FIGS. 8, 9A, and 9B, active patterns ACT may be formed on a semiconductor substrate 100. The formation of the active patterns ACT may include forming first mask patterns on the semiconductor substrate 100 and using the first mask patterns as an etching mask to etch an upper portion of the semiconductor substrate 100. The upper portion of the semiconductor substrate 100 may be etched to form in the semiconductor substrate 100 a trench that exposes lateral surfaces of the active patterns ACT. A device isolation layer 102 may be formed to fill the trench. The formation of the device isolation layer 102 may include forming on the semiconductor substrate 100 a device isolation dielectric layer that fills the trench and planarizing the device isolation dielectric layer until a top surface of the semiconductor substrate 100 is exposed.

Word lines WL may be formed in the semiconductor substrate 100, which run across the active patterns ACT and the device isolation layer 102. The word lines WL may be spaced apart from each other in a first direction D1, and may extend along a second direction D2. Each of the word lines WL may include a gate electrode GE, a gate dielectric pattern GI, and a gate capping pattern GC. The gate electrode GE may penetrate upper portions of the active patterns ACT and the device isolation layer 102. The gate dielectric pattern GI may be positioned between the gate electrode GE and the active patterns ACT and between the gate electrode GE and the device isolation layer 102. The gate capping pattern GC may be positioned on a top surface of the gate electrode GE.

The formation of the gate electrode GE and the gate dielectric pattern GI may include forming in the semiconductor substrate 100 grooves that penetrate upper portions of the active patterns ACT and the device isolation layer 102, forming a gate dielectric layer that covers an inner surface of each of the grooves, forming a gate electrode layer that fills each of the grooves, and planarizing the gate dielectric layer and the gate electrode layer until the top surface of the semiconductor substrate 100 is exposed. The formation of the gate capping pattern GC may include recessing an upper portion of the gate electrode GE to form an empty area in each of the grooves, forming a gate capping layer that fills the empty area, and planarizing the gate capping layer until the top surface of the semiconductor substrate 100 is exposed.

A first impurity region 110a and second impurity regions 110b may be formed in each of the active patterns ACT. The formation of the first and second impurity regions 110a and 110b may include using the gate capping pattern GC and the device isolation layer 102 as a mask to implant the active patterns ACT with impurities having the same conductivity type.

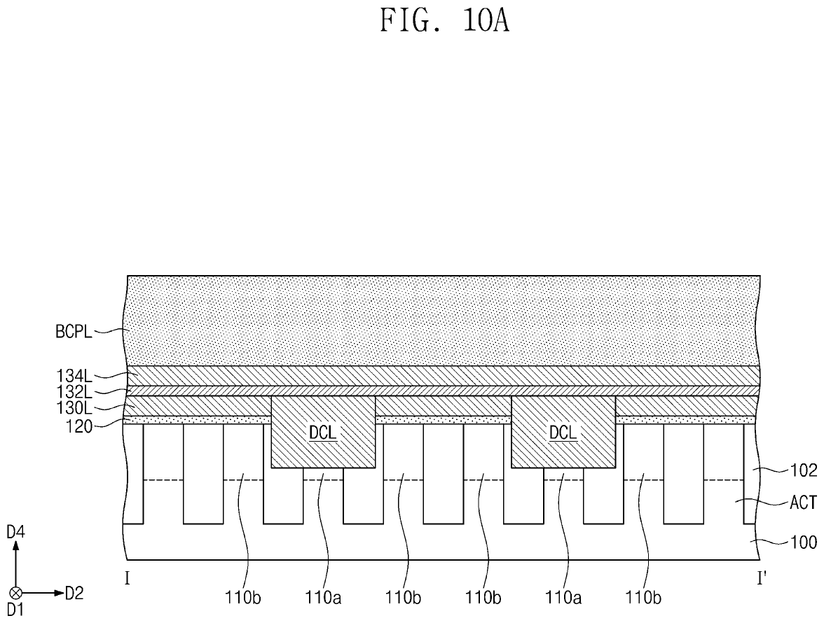

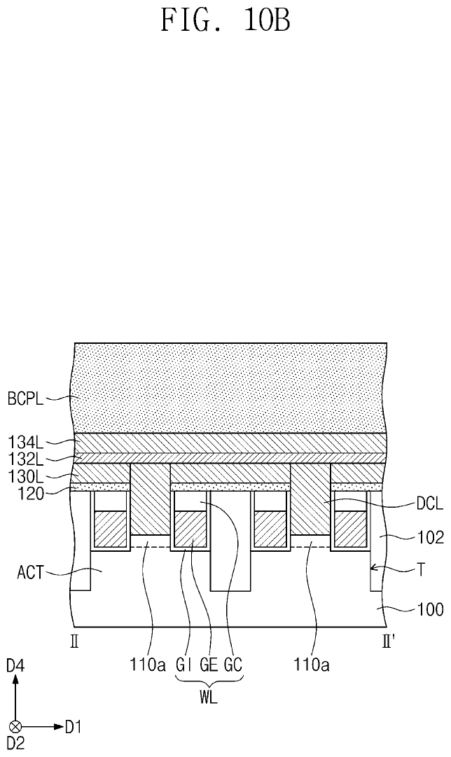

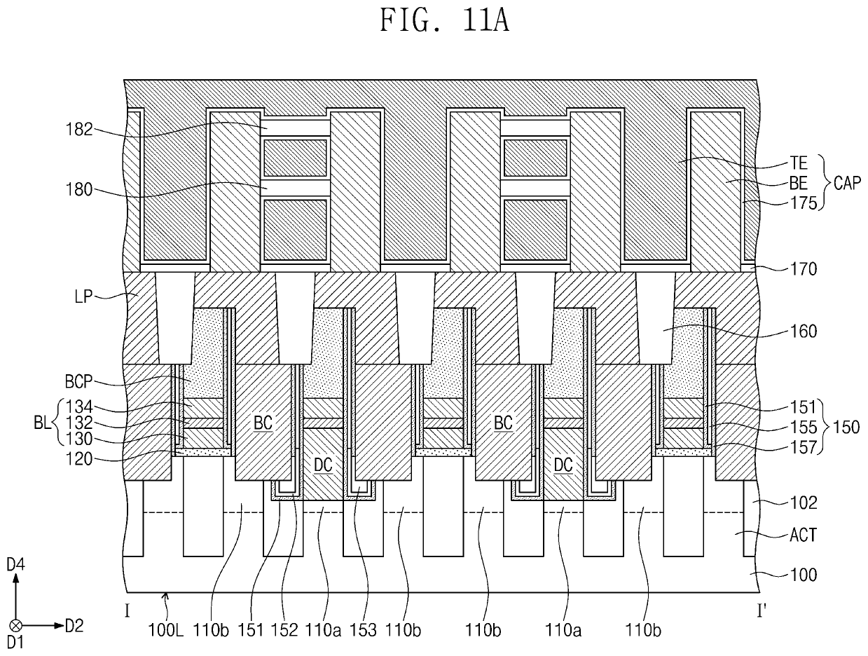

Referring to FIGS. 10A and 10B, a dielectric layer 120 may be formed on the semiconductor substrate 100. The dielectric layer 120 may cover the active patterns ACT, the device isolation layer 102, and the word lines WL. A lower conductive layer 130L may be stacked on the dielectric layer 120. Afterwards, recess regions may be formed to extend into the active patterns ACT and the device isolation layer 102, while penetrating the dielectric layer 120 and the lower conductive layer 130L. The formation of the recess regions may include forming on the lower conductive layer 130L a second mask pattern that defines areas where the recess regions will be formed, and using the second mask pattern as an etching mask to etch the lower conductive layer 130L, the dielectric layer 120, the active patterns ACT, and the device isolation layer 102. Thereafter, the second mask pattern may be removed.

A bit-line contact layer DCL may be formed to fill the recess regions. The formation of the bit-line contact layer DCL may include forming on the lower conductive layer 130L the bit-line contact layer DCL that fills the recess regions, and planarizing the bit-line contact layer DCL until a top surface of the lower conductive layer 130L is exposed. Thus, the bit-line contact layer DCL may be formed in the recess regions.

A lower barrier layer 132L, an upper conductive layer 134L, a diffusion barrier layer 136L, a bit-line capping layer BCPL may be sequentially formed on the lower conductive layer 130L and the bit-line contact layer DCL. The lower barrier layer 132L may cover the top surface of the lower conductive layer 130L and a top surface of the bit-line contact layer DCL. Each of the lower barrier layer 132L, the upper conductive layer 134L, and the bit-line capping layer BCPL may be formed by using physical vapor deposition (PVD), chemical vapor deposition (CVD), or atomic layer deposition (ALD).

The formation of the upper conductive layer 134L may be the first semiconductor fabrication process step (S10) discussed in FIG. 2. The formation of the bit-line capping layer BCPL may be the second semiconductor fabrication process step (S30) discussed in FIG. 2. For example, the upper conductive layer 134L may include a metallic material, such as tungsten (W), and the bit-line capping layer BCPL may include a dielectric material, such as one or more of silicon oxide, silicon nitride, and silicon oxynitride. In addition, the substrate degassing step (S20) may be included between the formation of the upper conductive layer 134L and the formation of the bit-line capping layer BCPL. Thus, after removal of residual gas (e.g., H₂, Cl₂, and/or HCl) present in the upper conductive layer 134L, the bit-line capping layer BCPL may be formed. The reduction in residual gas may reduce the occurrence of defects in the upper conductive layer 134L, and the bit-line capping layer BCPL may be uniformly formed. As a result, it may be possible to provide a semiconductor memory device with improved electrical properties.

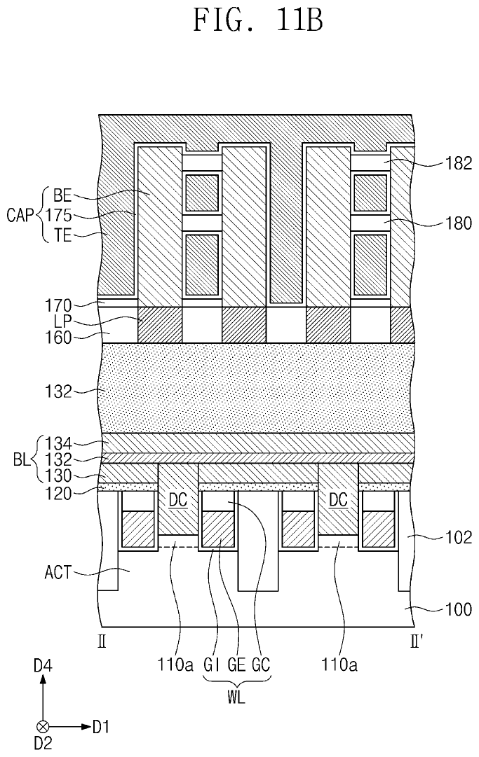

Referring to FIGS. 11A and 11B, the upper conductive layer 134L, the lower barrier layer 132L, and the lower conductive layer 130L may be sequentially etched to thereby form bit lines BL. The bit lines BL may be formed on the dielectric layer 120, while running across the word lines WL. The bit lines BL may extend in the first direction D1 and may be spaced apart from each other in the second direction D2. Each of the bit lines BL may include an upper conductive pattern 134, a lower barrier pattern 132, and a lower conductive pattern 130.

The bit-line contact layer DCL may be etched to form bit-line contacts DC. The bit-line contacts DC may be correspondingly positioned below the bit lines BL, and may be spaced apart from each other in the first direction D1. The lower conductive patterns 130 and the bit-line contacts DC may be alternately arranged along the first direction D1.

First, second, and third spacers 151, 155, and 157 may be sequentially formed on a lateral surface of each of the bit line BL and the bit-line capping pattern BCP. For example, the first spacer 151 may be positioned between the bit line BL and the second spacer 155, and the first and second spacers 151 and 155 may be positioned between the bit line BL and the third spacer 157. The formation of the first, second, and third spacers 151, 155, and 157 may include forming first to third spacer layers and anisotropically etching the first to third spacer layers. The first, second, and third spacers 151, 155, and 157 may constitute a bit-line spacer 150. The bit-line spacer 150 may extend in the first direction D1 along the lateral surface of each of the bit line BL and the bit-line capping pattern BCP.

On the semiconductor substrate 100, storage node contacts BC may be formed between the bit lines BL. The formation of the storage node contacts BC may include forming on the semiconductor substrate 100 a contact conductive layer that fills a space between the bit lines BL, planarizing the contact conductive layer until a top surface of the bit-line capping pattern BCP is exposed, and patterning the planarized contact conductive layer. The storage node contacts BC may be spaced apart from each other in the second direction D2 between a pair of neighboring bit lines BL.

Landing pads LP may be formed on the storage node contacts BC and the bit-line capping patterns BCP. The formation of the landing pads LP may include forming dielectric fences between the storage node contacts BC, forming a conductive layer that covers the storage node contacts BC, the dielectric fences, and the bit-line capping patterns BCP, and patterning the conductive layer. After that, a first upper dielectric layer 160 may be formed to fill a space between the landing pads LP.

An etch stop layer 170 may be formed on the landing pads LP and the first upper dielectric layer 160. Bottom electrodes BE may be correspondingly formed on the landing pads LP. Each of the bottom electrodes BE may penetrate the etch stop layer 170 to come into connection with a corresponding landing pad LP.

An upper support pattern 182 may be formed on upper sidewalls of the bottom electrodes BE, and may support the upper sidewalls of the bottom electrodes BE. A lower support pattern 180 may be formed on lower sidewalls of the bottom electrodes BE, and may support the lower sidewalls of the bottom electrodes BE. A dielectric layer 175 may be formed to cover surfaces of the bottom electrodes BE and surfaces of the upper and lower support patterns 182 and 180. A top electrode TE may be formed to fill a space between the bottom electrodes BE. The bottom electrodes BE, the dielectric layer 175, and the top electrode TE may constitute a capacitor structure CAP. For example, a semiconductor device according to some embodiments of the present inventive concepts may be a semiconductor memory device, for example, a dynamic random access memory (DRAM).

The substrate degassing method according to the embodiments may be used to degass a substrate between layer formation steps. For example, the substrate degassing method may be used between the formation of the upper conductive layer 134L and the formation of the bit-line capping layer BCPL. In a substrate degassing method and a substrate fabrication method using the same according to some embodiments of the present inventive concepts, a cyclic pumping may be employed to remove a gas that remains in a substrate. For example, a high vacuum state and a pumping state may be alternately performed to effectively degas the substrate. In the high vacuum state, a residual gas in the substrate may be outwardly discharged, and in the pumping state, the discharged residual gas may outwardly move from a process chamber. Accordingly, the possibility of a line, such as a metal conductive line, being damaged by residual gas in a subsequent process is reduced, and thus the semiconductor device may increase in reliability.

Although the present invention has been described in connection with the embodiments of the present invention illustrated in the accompanying drawings, it will be understood to those skilled in the art that various changes and modifications may be made without departing from the technical spirit and essential feature of the present invention. It therefore will be understood that the embodiments described above are just illustrative but not limitative in all aspects.

What is claimed is:

1. A substrate degassing method, comprising:
operating a vacuum pump associated with a process chamber to remove gas from the process chamber;
preparing a substrate in the process chamber;
blocking introduction of gas into the process chamber; and
repeatedly opening and closing a pump valve, wherein the pump valve is opened at least two times and closed at least two times,
wherein the pump valve inhibits the vacuum pump from removing gas from the process chamber when closed and permits the vacuum pump to remove gas from the process chamber when opened,
wherein when closed, the pump valve remains closed for a first time period,
wherein when open, the pump valve remains open for a second time period, and
wherein the first time period is greater than the second time period.

2. The substrate degassing method of claim 1, further comprising:
measuring a pressure of the process chamber.

3. The substrate degassing method of claim 1, further comprising analyzing a residual gas exhausted from the process chamber,
wherein the residual gas includes at least one of H₂, Cl₂, or HCl.

4. The substrate degassing method of claim 3, wherein analyzing the residual gas includes using a matrix-assisted laser desorption ionization-time of flight (MALDI-TOF) mass spectrometer.

5. The substrate degassing method of claim 1, wherein the first time period has the same duration each time the pump valve is closed and the second time period has the same duration each time the pump valve is opened.

6. The substrate degassing method of claim 2, wherein, as the pump valve is repeatedly opened and closed, the pressure of the process chamber increases and then decreases.

7. The substrate degassing method of claim 1, wherein the process chamber includes:
a gas supply unit configured to supply a gas to the process chamber;
a lower plate disposed in an interior of the process chamber;
an upper plate disposed above the lower plate in the interior of the process chamber; and
a support that connects the lower plate to the upper plate and supports a substrate introduced into the process chamber.

8. The substrate degassing method of claim 2, wherein opening and closing the pump valve includes:
providing a controller with information about the pressure of the process chamber; and
transmitting an electrical signal of the controller to the pump valve based on the information about the pressure of the process chamber.

9. The substrate degassing method of claim 8, wherein
When the pump valve is closed and the pressure of the process chamber is equal to or greater than a first pressure, the electrical signal of the controller drives the pump valve to open, and
when the pump valve is in an open state and the pressure of the process chamber is equal to or less than a second pressure, the electrical signal of the controller drives the pump valve to close.

10. The substrate degassing method of claim 9, wherein the first time period is increased after the pump valve is opened a first time.

11. A semiconductor fabrication method, comprising:
performing a first semiconductor fabrication process to deposit a first layer on a substrate;
degassing the substrate; and
performing a second semiconductor fabrication process to deposit a second layer on the substrate that is different from the first layer,
wherein degassing the substrate includes:
operating a vacuum pump associated with a process chamber to remove gas from the process chamber;
blocking introduction of gas into the process chamber;
closing a pump valve for a first time period; and
opening the pump valve for a second time period less than the first time period,
wherein the pump valve inhibits the vacuum pump from removing gas from the process chamber when closed and permits the vacuum pump to remove gas from the process chamber when opened, and
wherein closing the pump valve and opening the pump valve are each performed at least two times.

12. The semiconductor fabrication method of claim 11, wherein a temperature in the process chamber during the second semiconductor fabrication process is greater than a temperature in the process chamber during the first semiconductor fabrication process.

13. The semiconductor fabrication method of claim 11, wherein the second semiconductor fabrication process is performed in the process chamber.

14. The semiconductor fabrication method of claim 11, wherein
the first layer deposited during the first semiconductor fabrication process is comprised of a metal, and
the second layer deposited during the second semiconductor fabrication process is comprised of a dielectric material.

15. The semiconductor fabrication method of claim 11, wherein a gas used for the first semiconductor fabrication process comprises hydrogen.

16. A method of fabricating a semiconductor memory device, the method comprising:
forming a device isolation layer on a semiconductor substrate to define active patterns;
forming word lines that extend in a first direction crossing the active patterns and that are buried in the semiconductor substrate;
forming bit lines on the active patterns and the word lines, the bit lines extending in a second direction that intersects the first direction;
removing a residual gas from the bit lines; and
forming a bit-line capping pattern on the bit line,
wherein removing the residual gas in the bit lines includes:
blocking introduction of gas into a process chamber; and
cyclically changing a pressure of the process chamber.

17. The method of claim 16, wherein cyclically changing the pressure of the process chamber includes:
closing a pump valve associated with the process chamber; and
opening the pump valve,
wherein a time period for which the pump valve is closed is greater than a time period for which the pump valve is opened.

18. The method of claim 16, wherein removing the residual gas in the bit lines and forming the bit-line capping pattern are in-situ performed.

19. The method of claim 16, after forming the bit-line capping pattern, further comprising:
forming a storage node contact;
forming a landing pad on the storage node contact; and
forming a data storage structure on the landing pad.

20. The method of claim 16, wherein
the bit lines are formed from a material comprising tungsten, and
the residual gas in the bit lines includes hydrogen.
